(19) United States
(12) Patent Application Publication
(10) Pub. No.: US 2024/0363586 A1
(43) Pub. Date: Oct. 31, 2024

(54) SEMICONDUCTOR PACKAGE AND FORMING METHOD OF THE SAME

(71) Applicant: Taiwan Semiconductor Manufacturing Company, Ltd., Hsinchu (TW)

(72) Inventors: Su-Chun Yang, Hsinchu County (TW); Jih-Churng Twu, Hsinchu County (TW); Jui Hsuan Tsai, Taipei City (TW); Chiao-Chun Chang, Hsinchu County (TW); Chung-Shi Liu, Hsinchu City (TW); Chen-Hua Yu, Hsinchu City (TW)

(73) Assignee: Taiwan Semiconductor Manufacturing Company, Ltd., Hsinchu (TW)

(21) Appl. No.: 18/307,793

(22) Filed: Apr. 26, 2023

(51) Int. Cl. H01L 25/065; H01L 21/56; H01L 21/82; H01L 23/00; H01L 23/31; H01L 25/10

(52) U.S. Cl. CPC H01L 25/0652; H01L 21/561; H01L 21/565; H01L 21/82; H01L 23/3135; H01L 24/08; H01L 24/16; H01L 24/32; H01L 24/73; H01L 24/80; H01L 24/96; H01L 24/97; H01L 25/105; H01L 24/48; H01L 2224/08145; H01L 2224/16227; H01L 2224/32225; H01L 2224/48227; H01L 2224/73204; H01L 2224/80895; H01L 2224/80896; H01L 2224/96; H01L 2224/97; H01L 2225/1023; H01L 2225/1058; H01L 2924/183

(57) ABSTRACT

A semiconductor package includes a first integrated circuit, a plurality of second integrated circuits, at least one adhesion layer and a molding compound. The second integrated circuits are bonded onto the first integrated circuit. The at least one adhesion layer extends between the second integrated circuits and on sidewalls of the second integrated circuits. The molding compound extends between the second integrated circuits and on the at least one adhesion layer, wherein a surface of the at least one adhesion layer facing away from the first integrated circuit is substantially coplanar with a surface of the molding compound facing away from the first integrated circuit.

### BACKGROUND

In recent years, semiconductor industry has strived to continually reduce feature size and power consumption of various electronic components, while on the other hand increasing device density, wire density and operation frequency of the electronic components. These advanced electronic components also require smaller packages that utilize less area than packages of the past.

Three dimensional integrated circuit (3DIC) is a recent development in semiconductor packaging in which multiple semiconductor dies are stacked upon one another. 3DIC provides improved integration density and other advantages, such as greater operation speed and higher bandwidth, because of the decreased length of interconnects between the stacked dies. However, there are quite a few challenges to be overcome for the technology of 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E are schematic cross-sectional views of various stages in a method of forming a package structure according to some embodiments.

FIG. 2A and FIG. 2B are an example of FIG. 1C according to some embodiments of the present disclosure.

FIG. 3 is a schematic cross-sectional view illustrating a semiconductor package singulated from the package structure as shown in FIG. 1E, according to some embodiments of the present disclosure.

FIG. 4 is a schematic cross-sectional view illustrating a package, according to some embodiments of the present disclosure.

FIG. 5 is a schematic cross-sectional view illustrating a package, according to some embodiments of the present disclosure.

FIG. 6 is a schematic cross-sectional view illustrating a package structure, according to some other embodiments of the present disclosure.

FIG. 7 is a schematic cross-sectional view illustrating a semiconductor package according to some other embodiments of the present disclosure.

FIG. 8 illustrates a method of forming a semiconductor package according to some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be appreciated that the following embodiment(s) of the present disclosure provides applicable concepts that can be embodied in a wide variety of specific contexts. The embodiments are intended to provide further explanations but are not used to limit the scope of the present disclosure.

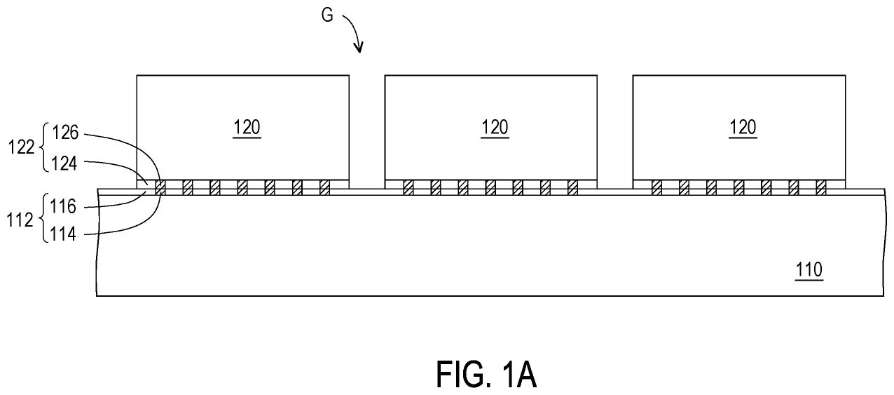

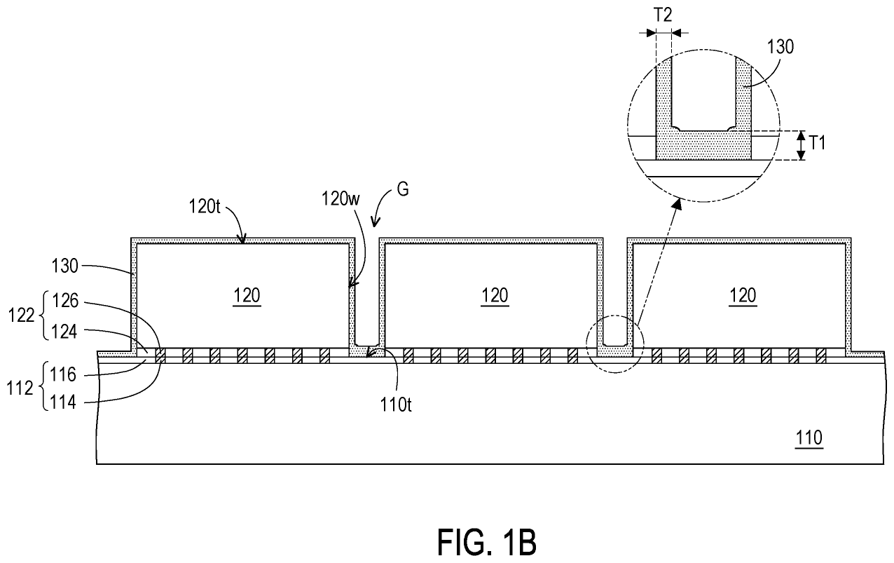

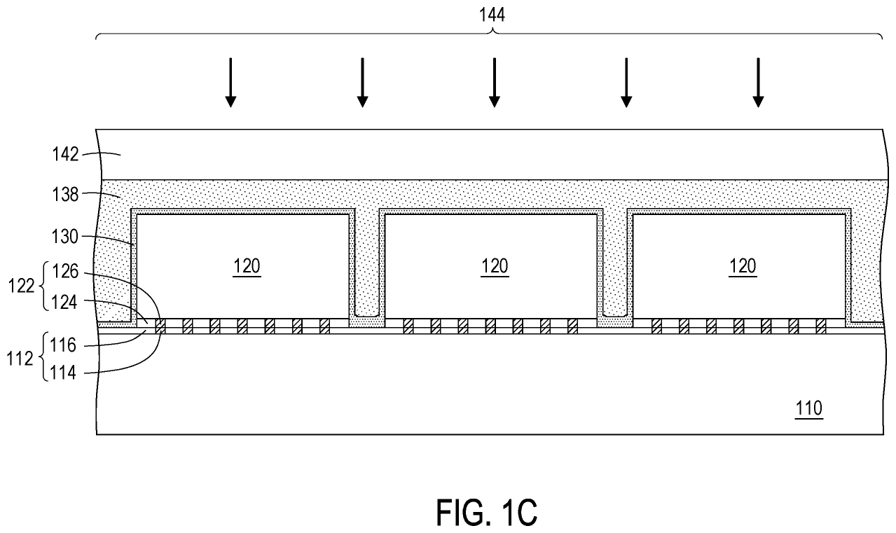

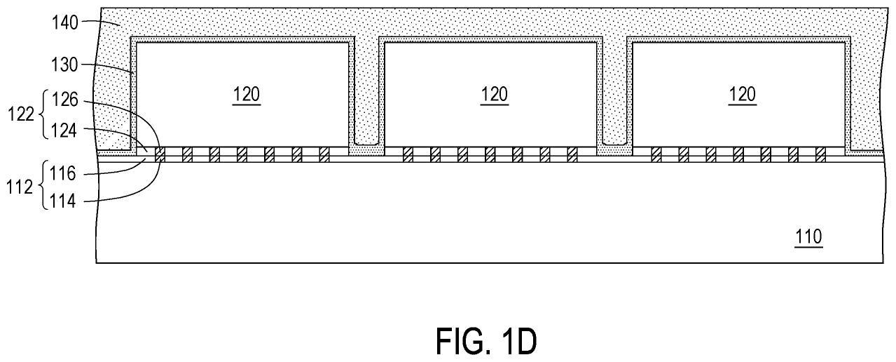

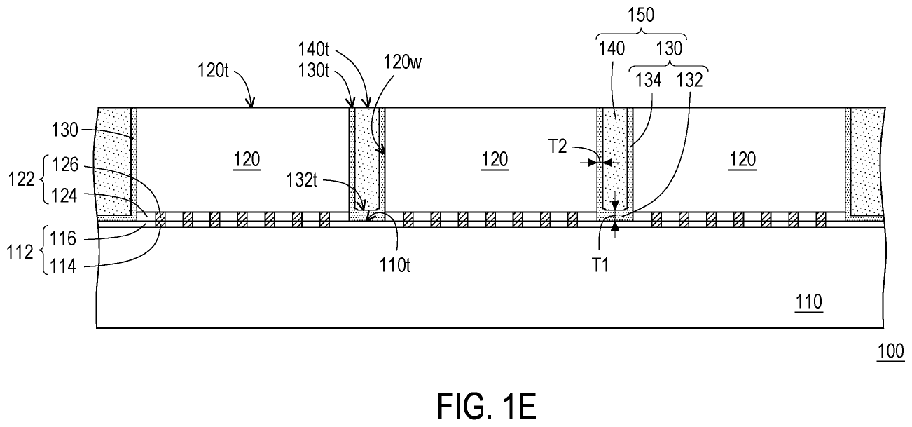

FIG. 1A to FIG. 1E are schematic cross-sectional views of various stages in a method of forming a package structure according to some embodiments.

Referring to FIG. 1A, a first integrated circuit 110 is provided, and a plurality of second integrated circuits 120 are bonded to the first integrated circuit 110. In some embodiments, the first integrated circuit 110 is a device wafer and includes active devices on a semiconductor substrate. The first integrated circuit 110 may further include a stack of metallization layers over the semiconductor substrate for out routing and interconnecting the active devices. A side of the semiconductor substrate at which the active devices and the metallization layers are formed is herein referred to as a front side of the first integrated circuit 110. On the other hand, the other side of the semiconductor substrate facing away from the active devices and the metallization layers is herein referred to as a back side of the first integrated circuit 110.

The second integrated circuits 120 are picked and placed onto the first integrated circuit 110, for example. The second integrated circuits 120 are separately placed on the die 110, and gaps G are defined between the second integrated circuits 120. In some embodiments, the second integrated circuits 120 are bonded to the front side of the first integrated circuit 110. In alternative embodiments, the second integrated circuits 120 are bonded to the back side of the first integrated circuit 110. The gap G may have a substantially vertical sidewall or a slant sidewall.

In some embodiments, the first integrated circuit 110 includes a bonding structure 112 on which the second integrated circuits 120 are bonded. In those embodiments where the second integrated circuits 120 are bonded to the front side of the first integrated circuit 110, the bonding structure 112 is disposed at the front side of the first integrated circuit 110. On the other hand, in those embodiments where the second integrated circuits 120 are bonded to the back side of the first integrated circuit 110, the bonding structure 112 is disposed at the back side of the first integrated circuit 110. The first integrated circuit 110 may be physically and electrically connected to the second integrated circuits 120 through the bonding structure 112. In some embodiments, the bonding structure 112 includes bonding pads 114 and a bonding dielectric layer 116 laterally surrounding the bonding pads 114. In those embodiments where the second integrated circuits 120 are bonded to the back side of the first integrated circuit 110, the first integrated circuit 110 may further include through substrate vias (not shown). The through substrate vias extend into the first integrated circuit 110 from a back surface of the semiconductor substrate of the first integrated circuit 110, to be electrically connected with the active devices and the metallization layers formed at the front side of the first integrated circuit 110. In other words, the through substrate vias provide conduction paths connecting the front side of the first integrated circuit 110 to the back side of the first integrated circuit 110.

The second integrated circuits 120 may be also referred to device dies. The second integrated circuits 120 may be singulated from other device wafer(s), and may be identical with or different from one another, in terms of size and types of the integrated circuits formed therein. As similar to the first integrated circuit 110, each second integrated circuit 120 may include active devices built on a semiconductor substrate, and may include a stack of metallization layers formed over the semiconductor substrate. A side of the semiconductor substrate at which the active devices and the metallization layers are formed is herein referred to as a front side of the second integrated circuit 120. On the other hand, the other side of the semiconductor substrate facing away from the active devices and the metallization layers is herein referred to as a back side of the second integrated circuit 120. In some embodiments, each second integrated circuit 120 is bonded to the first integrated circuit 110 by its front side. In alternative embodiments, each second integrated circuit 120 is bonded to the first integrated circuit 110 by its back side.

Further, as similar to the first integrated circuit 110, each second integrated circuit 120 may include a bonding structure 122 configured to bond to the first integrated circuit 110. In those embodiments where the second integrated circuits 120 are bonded to the first integrated circuit 110 by their front sides, the bonding structures 122 are respectively disposed at the front side of one of the second integrated circuits 120. On the other hand, in those embodiments where the second integrated circuits 120 are bonded to the first integrated circuit 110 by their back sides, the bonding structures 122 are respectively disposed at the back side of one of the second integrated circuits 120. The second integrated circuits 120 may be physically and electrically contacted with the first integrated circuit 110 through the bonding structure 122. In some embodiments, the bonding structure 122 includes bonding pads 124 and a bonding dielectric layer 126 laterally surrounding the bonding pads 124. Moreover, in those embodiments where the second integrated circuits 120 are bonded to the first integrated circuit 110 by their back sides, each of the second integrated circuits 120 may further include through substrate vias (not shown). The through substrate vias extend into the second integrated circuit 120 from a back surface of the semiconductor substrate of the second integrated circuit 120, to be electrically connected with the active devices and the metallization layers formed at the front side of the second integrated circuit 120. In other words, the through substrate vias in each second integrated circuit 120 may provide conduction paths bridging between the front and back sides of the second integrated circuit 120.

In some embodiments, the second integrated circuits 120 are bonded to the first integrated circuit 110 by a hybrid bonding manner. In these embodiments, the bonding pads 124 in the bonding structures 122 of the second integrated circuits 120 are respectively bonded to one of the bonding pads 114 in the bonding structure 112 of the first integrated circuit 110. In addition, the bonding dielectric layers 126 of the bonding structures 122 is bonded to the bonding dielectric layer 116 of the bonding structure 112. At least one thermal treatment may be used for establish bonding between the bonding pads 114, 124 and between the insulating layers 116, 126.

As mentioned before, the second integrated circuits 120 bonded to the first integrated circuit 110 are laterally spaced apart from one another, and the gaps G are formed between the second integrated circuits 120. The geometry of the gaps G affect the quality of the gap-filling material to be formed. For instance, increase of an aspect ratio of the gaps G (i.e., a ratio of gap height over gap width) may cause the gap-filling material flow to the periphery of the wafer/dic, and thus non-bond between the gap-filling material and the dies is observed. The aspect ratio of the gaps G increases as a thickness of the second integrated circuits 120 increases. In some embodiments, the thickness of the second integrated circuits 120 is equal to or greater than about 100 μm, and a separation between the second integrated circuits 120 is equal to or greater than about 60 μm. For example, the thickness of the second integrated circuits 120 is in a range of about 100 μm and about 750 μm and the separation between the second integrated circuits 120 is in a range of about 60 μm and about 240 μm. An aspect ratio of the gaps G may range from about 1 to 20, the adhesion between the gap-filling material and the second integrated circuits 120 and between the gap-filling material and the first integrated circuit 110 may be poor. In some embodiments, an adhesion layer is configured to enhance the adhesion between the gap-filling material and the second integrated circuits 120, and adhesion between the gap-filling material and the first integrated circuit 110.

Referring to FIG. 1B, an adhesion layer 130 is formed on exposed surfaces of the second

integrated circuits 120 and the first integrated circuit 110. In some embodiments, the adhesion layer 130 is conformally lining along surfaces 120t (e.g., top surfaces) and sidewalls 120w of the second integrated circuits 120 and a surface 110t (e.g., top surface) of the first integrated circuit 110 between the second integrated circuits 120. In other words, the adhesion layer 130 is conformally lining along bottom surfaces and sidewalls of the gaps G. In some embodiments, the adhesion layer 130 on the bottom surface of the gap G may have a substantially constant thickness T1, and the thickness T1 of the adhesion layer 130 at the corners of the gaps G may be a little thicker than at the bottom surface of the gaps G. The adhesion layer 130 on the sidewall of the gap G may have a substantially constant thickness T2. The thickness T1, t2 of the adhesion layer 130 is in a range of about 0.1 μm and about 10 μm, for example. In some embodiments, the thickness T2 is 10% to 95% of the thickness T1.

The adhesion layer 130 has a viscosity smaller than a molding compound to be formed, so as to improve the adhesion between the molding compound and the second integrated circuits 120, and the adhesion between the molding compound and the first integrated circuit 110. For example, the viscosity of the adhesion layer 130 is in a range of about 10 cp and about 100 cp while the viscosity of the molding compound is in a range of about 300 cp and about 400 cp. In some embodiments, the adhesion layer 130 is formed of a spin-on-glass (SOG) or a polymer such as polyimide, benzocyclobutene (BCB), polybenzoxazole (PBO) or the like. The SOG may include a solvent, and include a silicate based material, a siloxane based material or the like dispensed in the solvent. In some embodiments, a method for forming the adhesion layer 130 includes a coating process such as a spin coating process or a spray coating process, and further includes a curing process. The curing temperature is in a range of about 180° C. and about 300° C. For example, during the spin coating process, the bonded structure as shown in FIG. 1A is spun at a pre-determined speed. Meanwhile, the material (e.g., SOG/polymer material) of the adhesion layer 130 is spread on the spinning structure. Subsequently, the coated structure is baked to drive off solvent in the material (e.g., SOG/polymer material), and to solidify the coating for forming the adhesion layer 130. According to various embodiments, the thickness of the adhesion layer 130 may be controlled by limiting an amount of the SOG/polymer material, and/or adjusting parameters of the coating process (e.g., adjusting spin speed of a spin coating process).

Referring to FIG. 1C and FIG. 1D, a molding compound 140 is formed to fill up the gaps G and cover the adhesion layer 130 over the second integrated circuits 120. In some embodiments, the molding compound 140 is formed by applying a liquid molding compound 138 on the adhesion layer 130 over the first integrated circuit 110 and the second integrated circuit 120. The liquid molding compound 138 is applied in the form of a liquid. In some embodiments, the liquid molding compound 138 has a glass transition temperature (Tg) higher than about 150° C. The glass transition temperature (Tg) of the liquid molding compound 138 may also be between about 150° C. and 200° C. The material of the liquid molding compound 138 may include, and are not limited to, Cyclotrisiloxane-hexamethyl (C₆H₁₈O₃Si₃), Cyclohexene (C₆H₁₀), 2-Norbornene (C7H10), and 5-Ethylbicyclo [2.2.1]-2-heptene (C₉H₁₄). The liquid molding compound 138 may further include fillers therein, which is pre-mixed into the liquid molding compound 138 before it is applied on the adhesion layer 130. In some embodiments, the filler includes the particles of Al₂O₃, SiO₂. TiO₂, and/or the like. The diameter (size) of the filler may be not larger than about 30 μm. For example, the diameter (size) of the filler is in a range of about 5 μm and about 30 μm.

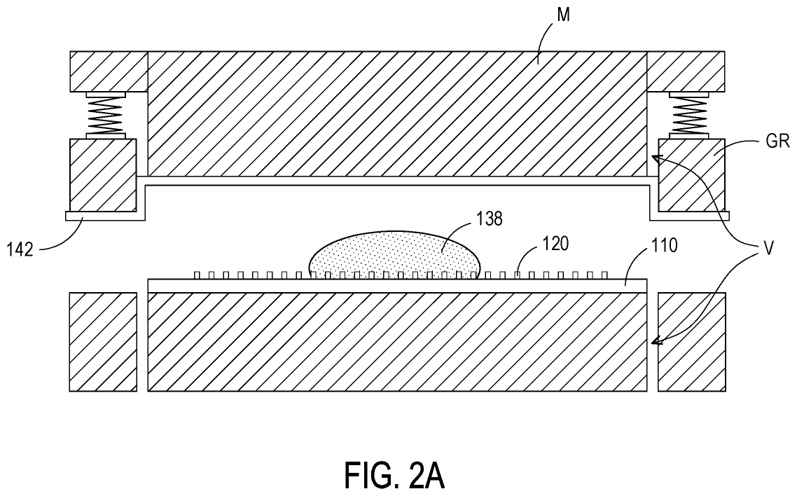

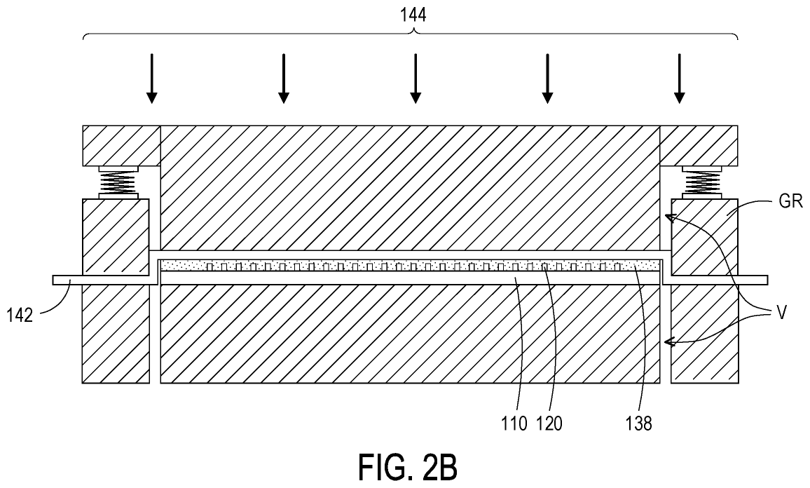

FIG. 2A and FIG. 2B are an example of FIG. 1C. In some embodiments, as shown in FIGS. 1C and 2B, a mold M is provided. The mold M may include a guide ring GR. The space V between the guide ring GR and the main body of the mold M may be vacuum. Then, the first integrated circuit 110 and the second integrated circuit 120 are disposed on a first side of the mold M, and the liquid molding compound 138 is applied on the adhesion layer 130 (omitted in FIG. 2A) over the first integrated circuit 110 and the second integrated circuit 120. A release film 142 is disposed on a second side of the mold M facing the liquid molding compound 138. The release film 142 may be formed of a soft material. Then, as shown in FIGS. 1C and 2B, a pressure, as shown as arrows 144, is applied on the release film 142. Furthermore, the release film 142 pushes some of the liquid molding compound 138 away from the second integrated circuits 120. With the release film 142 remaining being pushed against the liquid molding compound 138, a curing step is performed to cure and solidify the liquid molding compound 138. The liquid molding compound 138, after being solidified, is referred to as a molding compound 140 (FIG. 1D) hereinafter. In some embodiments, the curing is performed at a temperature smaller than 150° C., for a period of time between about 3 minutes and about 10 minutes. For example, the curing temperature is in a range of about 120° C. and about 140° C. The curing temperature may be adjusted depending on the material of the molding compound 140. In some embodiments, the molding compound 140 has a thickness greater than about 50 μm. The thickness of the molding compound 140 may also be between about 50 μm and about 200 μm. The release film 142 is then peeled off from the molding compound 140, which is now in a solid form. The resulting structure is shown in FIG. 1D.

Referring to FIG. 1E, a thickness reduction process may be performed on the molding compound 140. In some embodiments, the thickness of the molding compound 140 is reduced, so as to expose surfaces 120t (e.g., top surfaces) of the second integrated circuits 120. The thickness reduction process may be a planarization process such as a chemical mechanical chemical mechanical polishing (CMP) or the like. The thickness reduction process may be performed until the surfaces 120t (e.g., top surfaces) of the second integrated circuits 120 are exposed. During the thickness reduction process, the adhesion layer 130 may be also partially removed. After performing the thickness reduction process, surfaces 130t. 140t (e.g., top surfaces) of the adhesion layer 130 and the molding compound 140 are substantially coplanar with the surfaces 120t (e.g., top surfaces) of the second integrated circuits 120. In some embodiments, the surface 130t is the topmost surface of the adhesion layer 130, and the surface 130t is a flat top surface.

As shown in FIG. 1E, after partially removal, the adhesion layer 130 includes a planar portion 132 on the surface 110t (e.g., top surface) of the first integrated circuit 110 and a wall portion 134 on the sidewall 120w of the second integrated circuit 120. The planar portion 132 may have a substantially flat surface 132t (e.g., substantially flat top surface) facing away from the first integrated circuit 110. In some embodiments, as shown in FIG. 1E, the edge of the planar portion 132 may be much thicker. The uniformity of the substantially flat surface 132t is in a range of about 80% and about 100%, for example. The wall portion 134 may be physically connected to the planar portion 132, and the wall portion 134 has the surface 130t (e.g., flat top surface) facing away from the first integrated circuit 110. The surface 130t is substantially coplanar with the surfaces 120t, 140t (e.g., top surfaces) of the second integrated circuits 120 and the molding compound 140. In some embodiments, the wall portion 134 covers the sidewalls 120w of the second integrated circuits 120 entirely. In other words, the sidewalls 120w of the second integrated circuits 120 may be fully covered, and thus the adhesion layer 130 separates the molding compound 140 from the second integrated circuits 120. In some embodiments, the planar portion 132 has the substantially constant thickness T1, and the wall portion 134 has the substantially constant thickness T2 smaller the thickness T1. In some embodiments, the thickness T2 may be 10% to 95% of the thickness T1. The thickness T1, t2 of the planar portion 132 and the wall portion 134 is in a range of about 0.1 μm and about 10 μm, for example.

In some embodiments, the adhesion layer 130 continuously encloses the molding compound 140, and the adhesion layer 130 and the molding compound 140 may be cooperatively referred to as a composite gap filling structure 150. The composite gap filling structure 150 fills up the gaps G extending between the second integrated circuits 120, and laterally enclose each of the second integrated circuits 120. In some embodiments, the composite gap filling structure 150 conformally extends along sidewalls and bottom surfaces of the gaps G. The composite gap filling structure 150 is in laterally contact with the second integrated circuits 120 through the wall portions 134 of the adhesion layer 130, and the composite gap filling structure 150 is in contact with the underlying first integrated circuit 110 through the planar portions 132 of the adhesion layer 130. In some embodiments, a total thickness of the composite gap filling structure 150 is substantially equal to a thickness of the second integrated circuits 120, and a topmost surface (e.g., surfaces 130t and 140t) of the composite gap filling structure 150 is substantially coplanar with the surfaces (e.g., top surfaces) of the second integrated circuits 120. The composite gap filling structure 150 is configured to protect the second integrated circuits 120 from moisture absorption, corrosion, electrical noise and the like.

In some embodiments, since the viscosity of the adhesion layer 130 is smaller than the viscosity of the molding compound 140, the adhesion layer 130 improves the adhesion between the molding compound and the second integrated circuits 120, and the adhesion between the molding compound and the first integrated circuit 110. In addition, the liquid molding compound is used to form the molding compound 140 of the composite gap filling structure 150, and thus the molding compound 140 may excellently fill up the gaps G due to its great flowability. Accordingly, the composite gap filling structure 150 may also be formed with less defects (e.g., scams and/or voids) and improved gap-filling performance. As defects in the composite gap filling structure 150 are reduced or absent, the second integrated circuits 120 may be better protected by the composite gap filling structure 150 from possible damages including moisture absorption, corrosion, electrical noise and the like.

It should be noted that, although the composite gap filling structure 150 is described as having one adhesion layer 130, the composite gap filling structure 150 may alternatively have more than one adhesion layer 130 (e.g., two or more adhesion layers 130).

The resulting structure may be subjected to further packaging process(es). As an example, the current structure may be singulated.

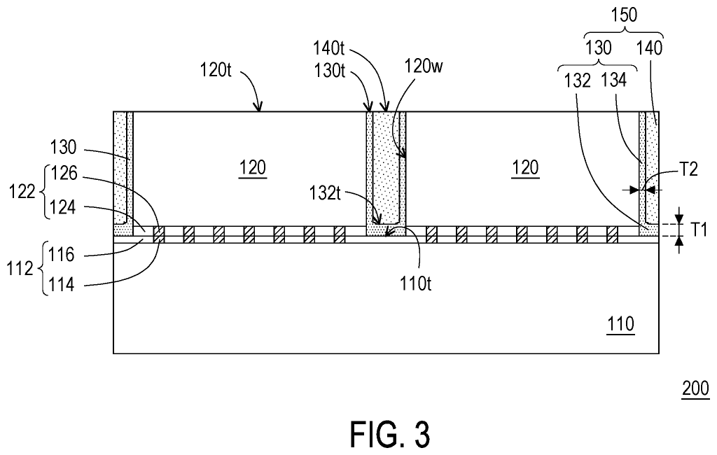

FIG. 3 is a schematic cross-sectional view illustrating a semiconductor package singulated from the package structure as shown in FIG. 1E, according to some embodiments of the present disclosure.

Referring to FIG. 3, the semiconductor package 200 is originated from the package structure 100 described with reference to FIG. 1E. A singulation process may be performed on the package structure 100, and the semiconductor package 200 is one of the structures singulated from the package structure 100. An integrated circuit 110′ (e.g., device die) bonded with some of the second integrated circuits 120 is singulated from the first integrated circuit 110 (e.g., device wafer). During the singulation, the composite gap filling structure 150 is cut along a sidewall of the integrated circuit 110′. Accordingly, the singulated composite gap filling structure 150 in the semiconductor package 200 may have sidewalls substantially flush with the sidewall of the integrated circuit 110′. In some embodiments, as shown in FIG. 3, the molding compound 140 is exposed, and a sidewall of the molding compound 140 is substantially flush with the sidewall of the integrated circuit 110′. In some embodiments, the adhesion layer 130 may be L-shaped.

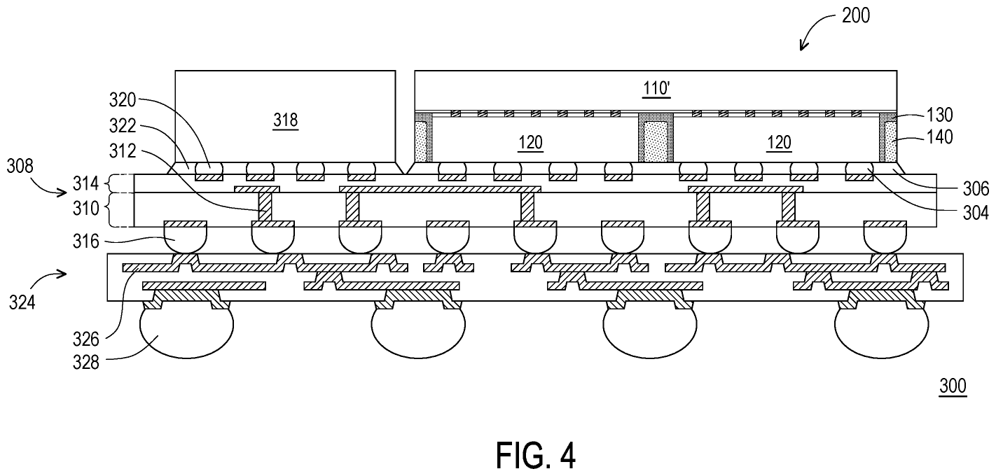

FIG. 4 is a schematic cross-sectional view illustrating a package 300, according to some embodiments of the present disclosure.

Referring to FIG. 4, the semiconductor package 200 as described with reference to FIG. 3 may be included in the package 300, but may be flipped over. In some embodiments, electrical connectors 304 are formed at a side of the semiconductor package 200, and functioned as inputs/outputs (I/Os) of the integrated circuits 110′, 120 in the semiconductor package 200. As an example, the electrical connectors 304 are deployed at a side of semiconductor package 200 close to the second integrated circuits 120 and the composite gap filling structure 150 (e.g., a bottom side of the semiconductor package 200). Further, a backside interconnection structure (not shown) for routing the second integrated circuits 120 to the electrical connectors 304 may be disposed between the second integrated circuits 120 and the electrical connectors 304, and between the composite gap filling structure 150 and the electrical connectors 304. An optional underfill 306 may be formed to laterally surround the electrical connectors 304.

In some embodiments, the semiconductor package 200 is bonded to an interposer 308. The electrical connectors 304 may be used to establish contact between the semiconductor package 200 and the interposer 308. The interposer 308 may include a substrate 310 (e.g., a semiconductor substrate or an organic substrate) and through substrate vias 312 penetrating through the substrate 310. In addition, the interposer 308 may further include an interconnection structure 314 lying along a side of the substrate 310 facing toward the semiconductor package 200. The electrical connectors 304 may be routed to the other side of the substrate 310 through interconnection clements (e.g., conductive wirings and conductive vias) in the interconnection structure 314 and the through substrate vias 312 penetrating the substrate 310. Moreover, electrical connectors 316 may be formed at the side of the substrate 310 facing away from the semiconductor package 200, as interface to another package component. As an example, the electrical connectors 316 may be controlled collapse chip connection (C4) bumps.

In addition to the semiconductor package 200, other package components may also be bonded to the interposer 308. For instance, a memory die 318 is also bonded to the interposer 308.

and arranged aside the semiconductor package 200. Electrical connectors 320 may be used for establishing contact between the memory die 318 and the interposer 308. As similar to the electrical connectors 304, the electrical connectors 320 may be micro-bumps. Optionally, the electrical connectors 320 may be laterally surrounded by an underfill 322.

Furthermore, the interposer 308 may be bonded onto a package substrate 324 via the electrical connectors 316. Interconnection clements 326 including conductive wirings and conductive vias may be formed in the package substrate 324, to establish routing paths between opposite sides of the package substrate 324. That is, the electrical connectors 316 at one side of the package substrate 324 may be routed to the other side of the package substrate 324 through these interconnection clements 326. In some embodiments, electrical connectors 328 as I/Os of the package 300 are disposed at the side of the package substrate 324 facing away from the interposer 308, and are electrically connected to the interconnection elements 326 in the package substrate 324. As an example, the electrical connectors 328 may be ball grid array (BGA) balls.

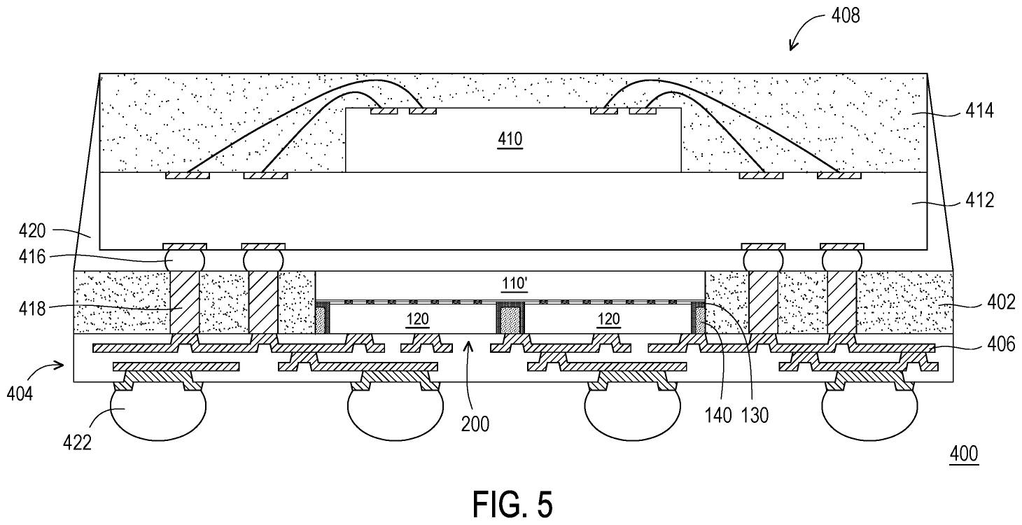

FIG. 5 is a schematic cross-sectional view illustrating a package 400, according to some embodiments of the present disclosure.

Referring to FIG. 5, as another example, the semiconductor package 200 singulated from the package structure 100 as shown in FIG. 1 is applied to a package 400. In the package 400, the semiconductor package 200 is laterally encapsulated by an encapsulant 402, which may be formed of a molding compound. A redistribution structure 404 is formed at a bottom side of the semiconductor package 200, and also extends along a bottom side of the encapsulant 402. Redistribution elements 406 including conductive wirings and conductive vias are formed in the redistribution structure 404, and are configured to rout the second integrated circuit 110′, 120 in the semiconductor package 200 to another side of the redistribution structure 404 via a fan-out manner. Although not shown, an optional backside interconnection structure for electrically connecting the semiconductor package 200 to the redistribution structure 404 may be disposed between the second integrated circuits 120 and the redistribution structure 404, and between the composite gap filling structure 150 and the redistribution structure 404.

In some embodiments, a semiconductor package 408 (e.g., memory package) is attached to a top side of the encapsulant 402. The semiconductor package 408 may include a semiconductor die 410 (e.g., a memory dic) and a package substrate 412 lying below the semiconductor dic 410. The semiconductor die 410 is bonded to the package substrate 412 (e.g., by a wire bonding manner), and may be laterally encapsulated by an encapsulant 414. Interconnection elements (not shown) formed in the package substrate 412 are configured to rout the semiconductor die 410 to a bottom side of the package substrate 412 facing toward the encapsulated semiconductor package 200. Further, electrical connectors 416 disposed at the bottom side of the substrate 412 may be used to establish contact between the semiconductor package 408 and the encapsulant 402. In these embodiments, through encapsulant vias 418 may be formed through the encapsulant 402 for connecting the electrical connectors 416 to the redistribution clements 406 in the redistribution structure 404. Therefore, the semiconductor package 408 may be routed to the bottom side of the redistribution structure 404 and/or interconnected with the semiconductor package 200 through the electrical connectors 416, the through encapsulant vias 418 and the redistribution elements 406 in the redistribution structure 404. In some embodiments, the electrical connectors 416 are laterally surrounded by an underfill 420. In addition, in some embodiments, electrical connectors 422 formed at the bottom side of the redistribution structure 404 are electrically connected to the redistribution clements 406 in the redistribution structure 404, and functioned as I/Os of the package 400.

In other embodiments where a package structure includes less or more than three composite gap filling structure 150, a die stacking structure singulated from the package structure may also be used in a variety of three dimensional semiconductor packages. For instance, such die stacking structure may replace the semiconductor package 200 in the package 300 or the semiconductor package 200 in the package 400.

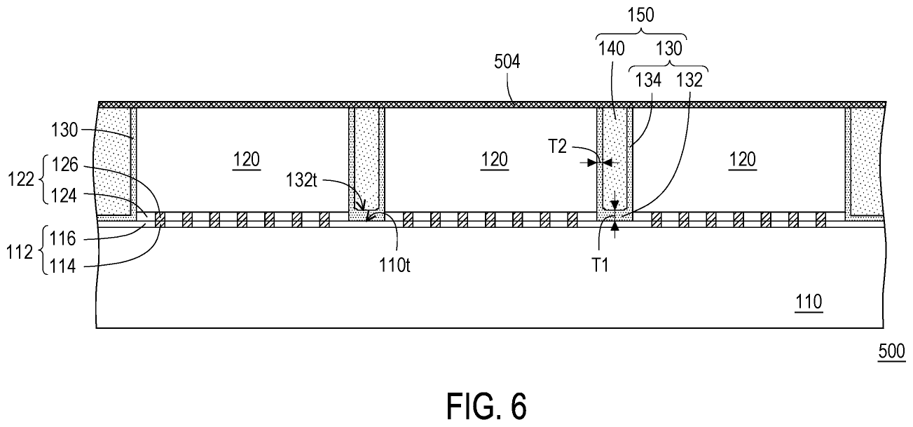

FIG. 6 is a schematic cross-sectional view illustrating a package structure 500, according to some other embodiments of the present disclosure.

As similar to the package structure 100 as described with reference to FIG. 1, the package structure 500 as shown in FIG. 6 also includes the first integrated circuit 110 and the second integrated circuits 120 bonded to the first integrated circuit 110. In addition, the package structure 500 also includes a composite gap filling structure 150 filled in the gaps G extending in between the second integrated circuits 120 and laterally surrounding each of the second integrated circuits 120.

In some embodiments, the package structure 500 includes a protection layer 504 extending along a top side of the package structure 500. The second integrated circuits 120 are covered by the protection layer 504, and may be protected by the protection layer 504 from possible damages while the package structure 500 is subjected to further processes. In addition, the composite gap filling structure 150 is also covered by the protection layer 504. In this way, the molding compound 140 is wrapped by the adhesion layer 130 and the protection layer 504. The protection layer 504 is formed of an insulating material, such as silicon nitride. In some embodiments, a method for forming the protection layer 504 includes a CVD process. In addition, in some embodiments, a thickness of the protection layer 504 ranges from about 500 Å to about 5000 Å.

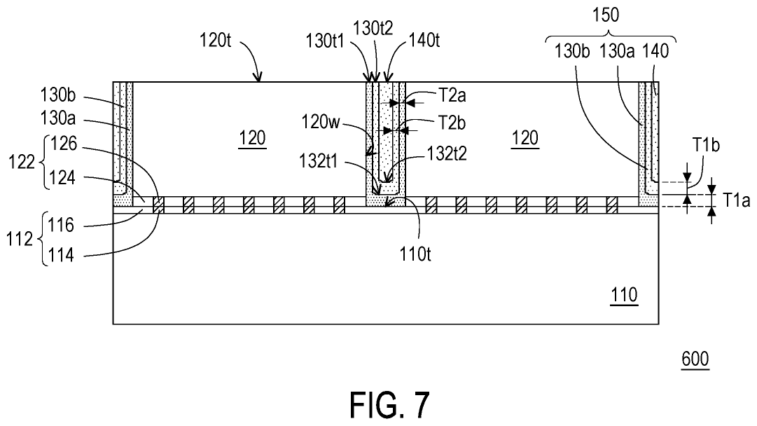

FIG. 7 is a schematic cross-sectional view illustrating a semiconductor package according to some other embodiments of the present disclosure.

The semiconductor package 600 partially illustrated in FIG. 7 is similar to the semiconductor package 200 as described with reference to FIG. 3, except that the composite gap filling structure 150 has a plurality of adhesion layers 130a, 130b between the molding compound 140 and the second integrated circuits 120. The adhesion layer 130b is disposed between the adhesion layer 130a and the molding compound 140. The adhesion layer 130b encloses the adhesion layer 130a, and the adhesion layers 130a, 130b enclose the molding compound 140. The formation, materials and structures of the adhesion layers 130a, 130b are similar to or the same as those of the adhesion layer 130. The material of the adhesion layer 130b is different from the adhesion layer 130b, and the viscosity of the adhesion layer 130b may be larger than the viscosity of the adhesion layer 130a. In some embodiments, the surfaces 130t1, 130t2 (e.g., top surfaces) of the adhesion layers 130a, 130b are substantially coplanar with the surfaces 140t, 120t (e.g., top surfaces) of the molding compound 140 and the second integrated circuits 120. The adhesion layers 130a, 130b may respectively have a substantially flat surface 13211, 13212 (e.g., substantially flat top surface) on the first integrated circuit 110 between the second integrated circuits 120. The adhesion layers 130a. 130b respectively have a substantially constant thickness T1a, T1b on the surface 110t of the first integrated circuit 110, and a substantially constant thickness T2a, T2b on the sidewall 120w of the second integrated circuit 120. The thickness Tlb of the adhesion layer 130b may be the same as or different from the thickness T1a of the adhesion layer 130a, and the thickness T2b of the adhesion layer 130b may be the same as or different from the thickness T2a of the adhesion layer 130a. For example, the thickness T1b of the adhesion layer 130b is larger than the thickness T1a of the adhesion layer 130a, and the thickness T2b of the adhesion layer 130b is larger than the thickness T2a of the adhesion layer 130a. Those skilled in the art may adjust a number of the adhesion layers 130 according to manufacturing process and/or die thickness. The present disclosure is not limited to the number of the adhesion layers 130.

Furthermore, the semiconductor package 600, combinations of the package structures 100 and combinations of the semiconductor package 600 described above can be respectively singulated to form a die stacking structure similar to the die stacking structure 200 described with reference to FIG. 3. In these stacking structures, the first integrated circuit 110 is singulated to form the first integrated circuit 110′. In addition, the die stacking structures may each be used in various semiconductor packages (e.g., the semiconductor packages 300, 400, 500 as described with reference to FIG. 4 to FIG. 6) as well.

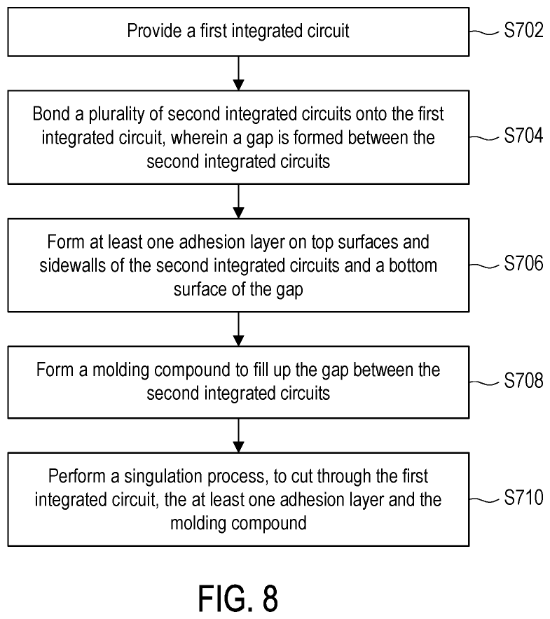

FIG. 8 illustrates a method of forming a semiconductor package according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S702, a first integrated circuit is provided. FIGS. 1A and 7 illustrate views corresponding to some embodiments of act S702.

At act S704, a plurality of second integrated circuits are bonded onto the first integrated circuit, wherein a gap is formed between the second integrated circuits. FIGS. 1A and 7 illustrate views corresponding to some embodiments of act S704.

At act S706, the at least one adhesion layer is formed on sidewalls and a bottom surface of the gap between the second integrated circuits. FIGS. 1B and 7 illustrate views corresponding to some embodiments of act S706.

At act S708, a molding compound is formed to fill up the gap between the second integrated circuits. FIGS. 1C, 1D, 2A, 2B and 7 illustrate views illustrate views corresponding to some embodiments of act S708.

At act S710, a singulation process is performed, to cut through the first integrated circuit, the at least one adhesion layer and the molding compound. FIGS. 3 and 7 illustrate views illustrate views corresponding to some embodiments of act S708.

As above, a composite gap filling structure is formed around the second integrated circuit for protecting the second integrated circuit from possible damages. The composite gap filling structure includes a molding compound and an adhesion layer between the second integrated circuit and the liquid molding compound. Due to the viscosity of the adhesion layer, the adhesion between the molding compound and the first and second integrated circuits is enhanced, even being filled in gaps with high aspect ratio. Thus, the composite gap filling structure provides good gap-filling performance.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good second integrated circuit to increase the yield and decrease costs.

In accordance with some embodiments of the disclosure, a semiconductor package includes a first integrated circuit, a plurality of second integrated circuits, at least one adhesion layer and a molding compound. The second integrated circuits are bonded onto the first integrated circuit. The at least one adhesion layer extends between the second integrated circuits and on sidewalls of the second integrated circuits. The molding compound extends between the second integrated circuits and on the at least one adhesion layer, wherein a surface of the at least one adhesion layer facing away from the first integrated circuit is substantially coplanar with a surface of the molding compound facing away from the first integrated circuit.

In accordance with some embodiments of the disclosure, a semiconductor package includes a first integrated circuit, a plurality of second integrated circuits, at least one adhesion layer and a molding compound. The second integrated circuits are bonded onto the first integrated circuit. The at least one adhesion layer extends between the second integrated circuits and has a substantially constant thickness on at least one sidewall of the second integrated circuits. The molding compound extends between the second integrated circuits and on the at least one adhesion layer.

In accordance with some embodiments of the disclosure, a method of forming a semiconductor package includes the following steps. A first integrated circuit is provided. A plurality of second integrated circuits are bonded onto the first integrated circuit, wherein a gap is formed between the second integrated circuits. At least one adhesion layer is formed on top surfaces and sidewalls of the second integrated circuits and a bottom surface of the gap. A molding compound is formed to fill up the gap between the second integrated circuits. A singulation process is performed, to cut through the first integrated circuit, the at least one adhesion layer and the molding compound.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first integrated circuit;
a plurality of second integrated circuits, bonded onto the first integrated circuit;
at least one adhesion layer, extending between the second integrated circuits and disposed on sidewalls of the second integrated circuits; and
a molding compound, extending between the second integrated circuits and on the at least one adhesion layer, wherein a surface of the at least one adhesion layer facing away from the first integrated circuit is substantially coplanar with a surface of the molding compound facing away from the first integrated circuit.

2. The semiconductor package according to claim 1, wherein the at least one adhesion layer continuously covers sidewalls of the second integrated circuits and a surface of the first integrated circuit between the second integrated circuits.

3. The semiconductor package according to claim 1, wherein the molding compound is in direct contact with the at least one adhesion layer.

4. The semiconductor package according to claim 1, wherein the surfaces of the at least one adhesion layer and the molding compound are substantially coplanar with surfaces of the second integrated circuits facing away from the first integrated circuit.

5. The semiconductor package according to claim 1, wherein a viscosity of the at least one adhesion layer is smaller than a viscosity of the molding compound.

6. The semiconductor package according to claim 1, wherein a material of the at least one adhesion layer comprises a spin-on-glass (SOG), polyimide, benzocyclobutene (BCB) or polybenzoxazole (PBO).

7. A semiconductor package, comprising:
a first integrated circuit;
a plurality of second integrated circuits, bonded onto the first integrated circuit;
at least one adhesion layer, extending between the second integrated circuits and having a substantially constant thickness on at least one sidewall of the second integrated circuits; and
a molding compound, extending between the second integrated circuits and on at least one the adhesion layer.

8. The semiconductor package according to claim 7, wherein the at least one adhesion layer entirely covers the at least one sidewall of the second integrated circuits.

9. The semiconductor package according to claim 7, wherein a topmost surface of the at least one adhesion layer facing away from the first integrated circuit is substantially coplanar with a top surface of the molding compound facing away from the first integrated circuit.

10. The semiconductor package according to claim 7, wherein the at least one adhesion layer extending on the first integrated circuit between the second integrated circuits has a substantially flat surface.

11. The semiconductor package according to claim 7, wherein a thickness of the at least one adhesion layer extending on the first integrated circuit between the second integrated circuits is larger than the substantially constant thickness.

12. The semiconductor package according to claim 7, wherein a viscosity of the at least one adhesion layer is smaller than a viscosity of the molding compound.

13. The semiconductor package according to claim 7, wherein a material of the at least one adhesion layer comprises a spin-on-glass (SOG), polyimide, benzocyclobutene (BCB) or polybenzoxazole (PBO).

14. The semiconductor package according to claim 7, wherein the at least one adhesion layer is in direct contact with the second integrated circuits.

15. A method of forming a semiconductor package, comprising:
providing a first integrated circuit;
bonding a plurality of second integrated circuits onto the first integrated circuit, wherein a gap is formed between the second integrated circuits;
forming at least one adhesion layer on top surfaces and sidewalls of the second integrated circuits and a bottom surface of the gap;
forming a molding compound to fill up the gap between the second integrated circuits; and
performing a singulation process, to cut through the first integrated circuit, the at least one adhesion layer and the molding compound.

16. The method of forming a semiconductor package according to claim 15, before performing the singulation process, further comprising removing portions of the molding compound and the at least one adhesion layer, wherein top surfaces of the molding compound and the at least one adhesion layer are substantially coplanar with the top surfaces of the second integrated circuits.

17. The method of forming a semiconductor package according to claim 15, wherein a method of forming the at least one adhesion layer comprises a coating process.

18. The method of forming a semiconductor package according to claim 15, wherein a material of the at least one adhesion layer comprises a spin-on-glass (SOG) or a polymer.

19. The method of forming a semiconductor package according to claim 15, wherein forming the molding compound comprises applying a liquid molding compound.

20. The method of forming a semiconductor package according to claim 15, wherein a curing temperature for forming the at least one adhesion layer is higher than a curing temperature for forming the molding compound.
